(19) United States
(12) Patent Application Publication
(10) Pub. No.: US 2025/0318293 A1
(43) Pub. Date: Oct. 9, 2025

(54) IMAGING SENSOR AND DEVICE WITH GATE CONTROLLED ISOLATION BETWEEN SHARED PIXELS

(71) Applicant: SONY SEMICONDUCTOR SOLUTIONS CORPORATION, Kanagawa (JP)

(72) Inventors: Arastoo Khalili, Brussels (BE); Lien Tu, Rochester, NY (US)

(73) Assignee: SONY SEMICONDUCTOR SOLUTIONS CORPORATION, Kanagawa (JP)

(21) Appl. No.: 18/630,134

(22) Filed: Apr. 9, 2024

(51) Int. Cl. H01L 27/146

(52) U.S. Cl. CPC H10F 39/8027; H10F 39/011; H10F 39/8063

(57) ABSTRACT

An imaging device including a plurality of recta shared pixels in which a potential barrier between the photoelectric conversion units of the recta shared pixels is controlled by a control gate. In a default mode, a first voltage is supplied to the control gate to establish an amount of separation between the photoelectric conversion units of the recta shared pixels that is lower or the same as or only slightly larger than the separation established by an intra-pixel separation structure. In another mode, a second voltage is supplied to the control gate to establish an amount of separation between the photoelectric conversion units of the recta shared pixels that is greater than in the default mode. The default mode is maintained during image acquisition, while the other mode is applied only during generation of charge by the photoelectric conversion units during phase detection autofocus operations.

### FIELD

The present disclosure relates to an imaging elements and imaging devices incorporating phase detection autofocus capabilities.

### BACKGROUND

Digital image sensors are commonly used in a variety of electronic devices, such as handheld cameras, security systems, telephones, computers, tablets, and machine vision systems to capture images. In order to ensure that the captured images are in focus, a variety of autofocus systems and techniques have been developed. For example, contrast detection and phase detection methods have been developed. Each method has advantages and disadvantages. For instance, contrast detection autofocus is generally slower than phase detection autofocus, but contrast detection autofocus can be more accurate than phase detection autofocus. Accordingly, many cameras and other electronic devices implement both contrast detection and phase detection methods.

In mirrorless imaging devices, and in single lens reflex cameras operating in a live view or movie mode, autofocus must be performed using pixels disposed on the image sensor itself. However, phase detection autofocus requires that specialized phase detection pixels be used. As the trend has been to provide increasing numbers of autofocus points, enabling autofocus to be performed with respect to image features in essentially all areas of the image frame, phase detection pixels that are capable of contributing image information, in addition to information used to focus the image, have become increasingly desirable.

A phase detection autofocus system typically includes photosensitive elements that are disposed in pairs. In some phase detection arrangements, a physical mask ensures that separate pixels within a pair receive light from opposite sides of the imaging lens. However, such systems can suffer from poor low light performance, and are not able to be used in an imaging mode. In other phase detection arrangements, each phase detection pixel includes a pair of photoelectric conversion units disposed under a common microlens. In such arrangements, isolation between the photoelectric conversion units within a pixel is important for enabling phase detection autofocus operations. In addition, the signals from the pixel pair can be used in an imaging mode. However, where the isolation between the pixels is great, charge in one pixel can overflow to the floating diffusion, rather than to the other pixel in the pair, resulting in deteriorated signal linearity.

### SUMMARY

Embodiments of the present disclosure provide imaging elements and imaging devices incorporating phase detection autofocus pixels in the form of multiple photodiodes, single microlens pixels, also known as recta shared pixels or recta phase detection (PD) pixels. Each recta shared pixel can include first and second (e.g. left and right or top and bottom) sub-pixels or photodiodes. In a phase detection auto focus (PDAF) mode, signals from the first and second photodiodes of a recta shared pixel are read out separately. In a viewing or imaging mode, the signal from the photodiodes of the recta shared pixel are read out as a combined signal. In the PDAF mode, it is desirable to maintain a high degree of separation between the first and second photodiodes. In the imaging mode, it is desirable to allow charge to pass from one of the first and second photodiodes to the other of the first and second photodiodes, in order to promote linearity of the output signal. In accordance with embodiments of the present disclosure, an amount of signal isolation between the first and second photodiodes within a recta phase detection pixel can be controlled. As a result, a high degree of isolation between the individual photodiodes of the recta phase detection pixel can be provided to promote accurate PDAF capabilities when the recta phase detection pixel is operated in an autofocus mode, and a reduced level of isolation can be provided to promote signal linearity when the recta PD pixel is operated in an imaging mode.

In accordance with embodiments of the present disclosure, control of the signal isolation between the individual photodiodes of a recta phase detection pixel is enabled by the creation of a variable potential barrier. More particularly, a control gate is disposed adjacent to the potential barrier between the individual photodiodes. By selecting a first gate voltage, a high separation ratio can be enabled in a phase detection autofocus mode, and by selecting a second gate voltage, good linearity in signal response across the entire recta shared pixel can be enabled in an imaging mode. Accordingly, in embodiments of the present disclosure, the control gate operates to control an amount of separation between the photodiodes of the recta shared pixel. More particularly, embodiments of the present disclosure are configured such that there is a relatively low degree of signal isolation between the sub-pixels with the control gate in a high or ON state, and such that there is a relatively high degree of isolation between the sub-pixels with the control gate in a low or OFF state. Moreover, at least some embodiments of the present disclosure maintain the control gate in a high or ON state for all operations except phase difference autofocus operations. On special application specific conditions, the control gate can have a usage-based reference voltage applied to allow for finer control of isolation between the two shared photodiode pairs. Accordingly, the control gate is maintained in an ON state as a default mode.

The control gate can be provided in any of a variety of configurations. For instance, the control gate can be disposed as a planar structure on a surface of a substrate in which the photodiodes of the first and second photodiodes are formed. As another example, the gate structure can be configured as a vertical gate. As yet another example, the control gate can be configured as a dual vertical gate. In accordance with still further embodiments of the present disclosure, the control gate can have elements or aspects that are the same as or similar to aspects of transfer gates provided for the individual photodiodes. For example, at least portions of the control gate can be in a same plane and can have a same shape as the transfer gates. As another example, at least portions of the control gate can be in a same plane and can have a same shape and size as the transfer gates.

Additional features and advantages of embodiments of the present disclosure will become more readily apparent from the following description, particularly when considered together with the accompanying drawings.

### BRIEF DESCRIPTION OF THE DRAWINGS

FIG. 1 is a diagram illustrating a schematic configuration example of a solid-state imaging device in accordance with embodiments of the present disclosure;

FIG. 2A is a cross-section in elevation of the photodiodes of a prior art recta shared pixel with a potential barrier fixed at a relatively high state;

FIG. 2B depicts the potential of the photodiodes of the prior art recta shared pixel of FIG. 2A;

FIG. 3A is a cross-section in elevation of the photodiodes of a prior art recta shared pixel with a potential barrier fixed at a relatively low state;

FIG. 3B depicts the potential of the photodiodes of the prior art recta shared pixel of FIG. 3A;

FIG. 4 is a plan view of a portion of an imaging device in accordance with embodiments of the present disclosure;

FIG. 5 is cross-section in elevation taken along section line 5-5′ of the imaging device of FIG. 4;

FIG. 6A is a cross-section in elevation of a recta shared pixel taken along section line 6A-6A′ of the imaging device of FIG. 4, with a variable potential barrier set at a relatively high state;

FIG. 6B is a cross-section in elevation of a recta shared pixel taken along section line 6B-6B′ of the imaging device of FIG. 4, with a variable potential barrier set at a relatively high state;

FIG. 6A′ is a cross-section in elevation of a recta shared pixel taken along section line 6A-6A′ of the imaging device of FIG. 4, with a variable potential barrier set at a relatively low state;

FIG. 6B′ is a cross-section in elevation of a recta shared pixel taken along section line 6B-6B′ of the imaging device of FIG. 4, with a variable potential barrier set at a relatively low state;

FIG. 7 is a plan view of a surface of the recta shared pixel of FIGS. 6A-6B′;

FIG. 8A is a bucket-concept diagram of the photodiodes of a shared pixel with a variable potential barrier set at a relatively low state in accordance with embodiments of the present disclosure;

FIG. 8B is a bucket-concept diagram of the photodiodes of the shared pixel with the variable potential barrier set at a relatively high state in accordance with embodiments of the present disclosure;

FIG. 9A depicts the potential of the photodiodes of a shared pixel with a variable potential barrier set at a relatively low state in accordance with embodiments of the present disclosure;

FIG. 9B depicts the potential of the photodiodes of the shared pixel with the variable potential barrier set at a relatively high state in accordance with embodiments of the present disclosure;

FIG. 10 is an example of a circuit configuration of a recta shared pixel in accordance with embodiments of the present disclosure;

FIG. 11A is a cross-section in elevation of a recta shared pixel in accordance with embodiments of the present disclosure;

FIG. 11B is a plan view of a recta shared pixel in accordance with embodiments of the present disclosure;

FIG. 12A is a cross-section in elevation of a recta shared pixel in accordance with other embodiments of the present disclosure;

FIG. 12B is a plan view of a recta shared pixel in accordance with other embodiments of the present disclosure;

FIG. 13A is a cross-section in elevation of a recta shared pixel in accordance with other embodiments of the present disclosure;

FIG. 13B is a plan view of a recta shared pixel in accordance with other embodiments of the present disclosure;

FIG. 14 is a block diagram of an imaging system incorporating an imaging device in accordance with embodiments of the present disclosure;

FIG. 15 is a flowchart depicting aspects of a method for operating an imaging device incorporating a recta shared pixel in accordance with embodiments of the present disclosure; and

FIG. 16 is a timing diagram depicting the operation of a recta shared pixel in accordance with embodiments of the present disclosure.

### DETAILED DESCRIPTION

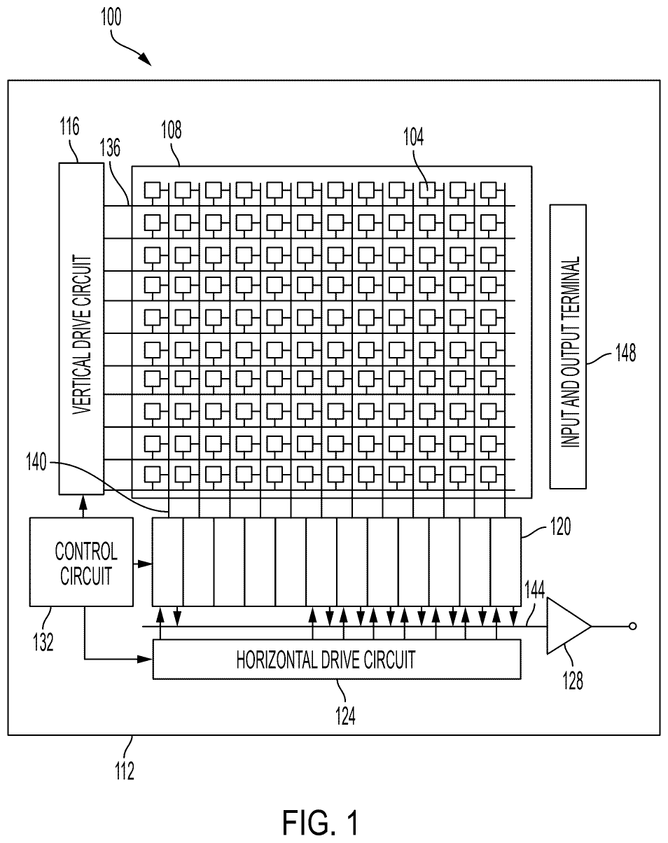

FIG. 1 is a diagram that depicts aspects of an imaging device or sensor 100 incorporating multiple photodiode, single microlens pixels, referred to herein as recta shared pixels 104, in accordance with embodiments of the present disclosure. As discussed herein, embodiments of the present disclosure enable a potential barrier between sub-pixels of a recta shared pixel 104 to be varied, according to an operating mode of the recta shared pixel 104. In general, the imaging sensor 100 includes a plurality of recta shared pixels 104 disposed in an array 108. The recta shared pixels 104 as disclosed herein are capable of selectively operating in a phase detection autofocus mode or in an imaging mode. Accordingly, all of the pixels of an imaging sensor 100 can be in the form of recta shared pixels 104 as disclosed herein. In accordance with other embodiments, an imaging device 100 can include conventional imaging pixels and/or conventional PDAF pixels, in addition to the phase detection auto focus and imaging recta shared pixels 104 as disclosed herein. The recta shared pixels 104 can be disposed within an array 108 having a plurality of rows and columns of recta shared pixels 104. Moreover, the recta shared pixels 104 are formed on or in a sensor substrate 112. In addition, one or more peripheral or other circuits can be formed in connection with the sensor substrate 112. Examples of such circuits include a vertical drive circuit 116, a column signal processing circuit 120, a horizontal drive circuit 124, an output circuit 128, and a control circuit 132. As described in greater detail elsewhere herein, each of the recta shared pixels 104 within an imaging device 100 in accordance with embodiments of the present disclosure includes a pair of photosensitive sites or photoelectric conversion elements, referred to herein as sub-pixels or photodiodes.

The vertical drive circuit 116 can, for example, be configured with a shift register, can operate to select a pixel drive wiring 136, and can supply custom voltage pulses for driving sub-pixels of recta shared pixels 104 through the selected drive wiring 136 in units of a row. The vertical drive circuit 116 can also selectively and sequentially scan elements of the array 108 in units of a row in a vertical direction, and supply the signals generated within the recta shared pixels 104 according to an amount of light they have received to the column signal processing circuit 120 through a vertical signal line 140.

The column signal processing circuit 120 can operate to perform signal processing, such as noise removal, on the signals output from the recta shared pixels 104. For example, the column signal processing circuit 120 can perform signal processing, such as correlated double sampling (CDS), to remove a specific fixed patterned noise of a selected recta shared pixel 104 and an analog to digital (A/D) conversion of the signal.

The horizontal drive circuit 124 can include a shift register. The horizontal drive circuit 124 can select each column signal processing circuit 120 in order by sequentially outputting horizontal scanning pulses, causing each column signal processing circuit 120 to output a pixel signal to a horizontal signal line 144. The output circuit 128 can perform predetermined signal processing with respect to the signals sequentially supplied from each column signal processing circuit 120 through the horizontal signal line 144. For example, the output circuit 128 can perform a buffering, black level adjustment, column variation correction, various digital signal processing, and other signal processing procedures. An input and output terminal 148 exchanges signals between the imaging device 100 and external components or systems.

The control circuit 132 can receive data for instructing an input clock, an operation mode, and the like, and can output data such as internal information related to the imaging device 100. Accordingly, the control circuit 132 can generate a clock signal that provides a standard for operation of the vertical drive circuit 116, the column signal processing circuit 120, and the horizontal drive circuit 124, and control signals based on a vertical synchronization signal, a horizontal synchronization signal, and a master clock. The control circuit 132 outputs the generated clock signal in the control signals to the various other circuits and components.

Accordingly, at least portions of an imaging device 100 in accordance with at least some embodiments of the present disclosure can be configured as a CMOS image sensor of a column A/D type in which column signal processing is performed.

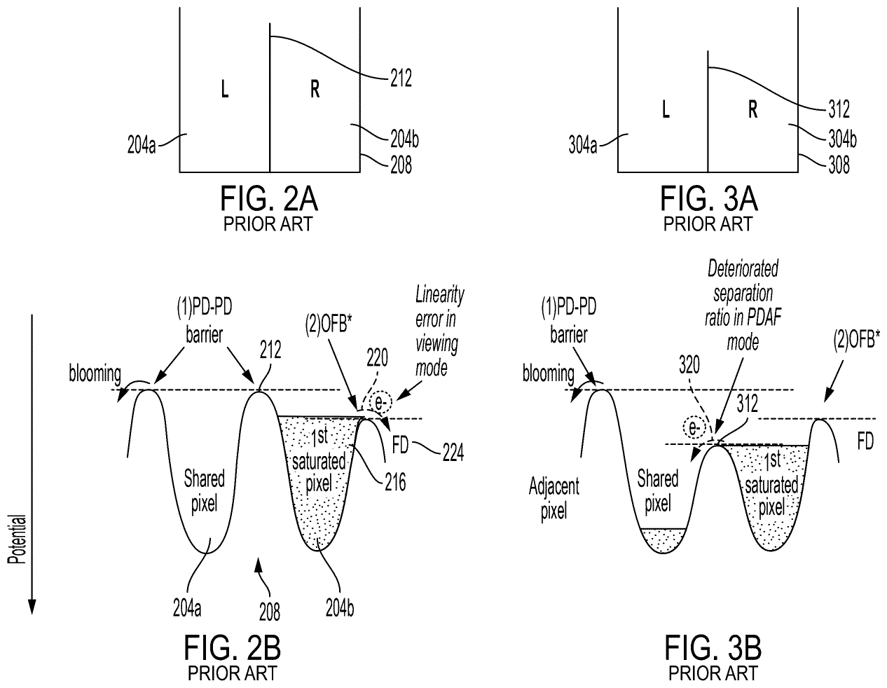

FIG. 2A is a cross-section in elevation of the photodiodes 204a and 204b of a prior art recta shared pixel 208 with a potential barrier 212 fixed at a relatively high state, and FIG. 2B depicts the potential 216 of the photodiodes 204a and 204b of the recta shared pixel 208 with the potential barrier 212 fixed at a relatively high state in accordance with the prior art. As shown in FIG. 2B, where one of the photodiodes 204 of the recta shared pixel 208 becomes saturated (e.g. the right side photodiode 204b in FIG. 2B), charge 220 can overflow to the floating diffusion 224, instead of to the other of the photodiodes 204 (e.g. the left side photodiode 204a in FIG. 2B). This loss of charge to the floating diffusion 224 results in a linearity error in the signal output by the recta shared pixel 208. In particular, charge lost to the floating diffusion 224 is not reflected in the signal output by the pixel 208. Accordingly, the performance of the recta shared pixel 208 having a potential barrier 212 fixed at a relatively high state is compromised in certain imaging operations.

FIG. 3A is a cross-section in elevation of the photodiodes 304a and 304b of a prior art recta shared pixel 308 with a potential barrier 312 fixed at a relatively low state, and FIG. 3B depicts the potential 316 of the photodiodes 304a and 304b of the recta shared pixel 308 with the potential barrier 312 fixed at a relatively low state in accordance with the prior art. As shown in FIG. 3B, where one of the photodiodes 304 of the recta shared pixel 308 becomes saturated (e.g. the right side photodiode 304b in FIG. 3B), charge 320 can overflow to the other of the photodiodes 304 (e.g. the left side photodiode 304 in FIG. 3B). That is, the relatively low potential barrier 312 between the photodiodes 304 results in a decreased separation ratio between those photodiodes 304. As a result of the relatively weak isolation between the photodiodes 304a and 304b, phase detection autofocus becomes difficult.

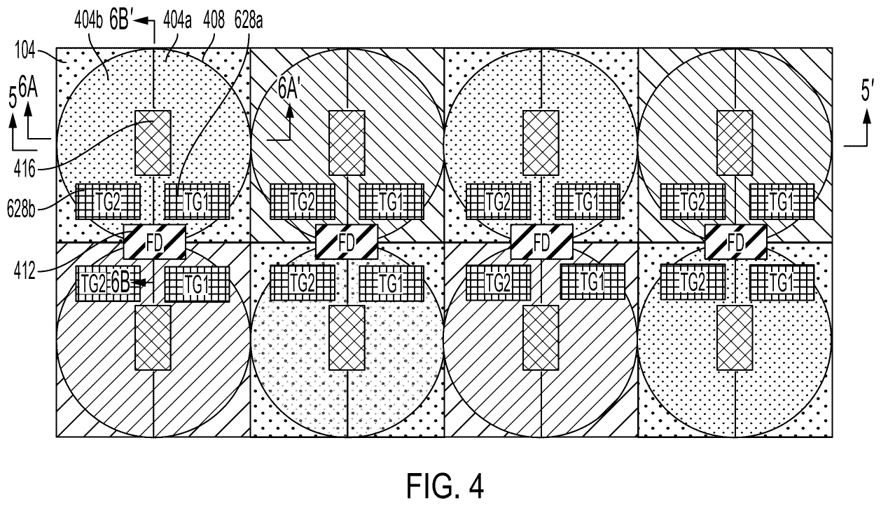

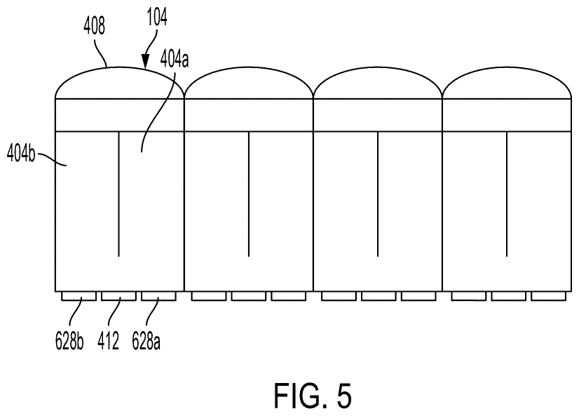

Embodiments of the present disclosure address the limitations of prior art recta shared pixels having fixed potential barriers by providing a variable potential barrier between photoelectric conversion regions diodes of the recta shared pixels. FIG. 4 is a plan view of a surface of a portion of an imaging device 100 including an array 108 of recta shared pixels 104 in accordance with embodiments of the present disclosure, and FIG. 5 is a cross-section in elevation taken along section line 5-5′ of FIG. 4. In this example, two recta shared pixels 104, each including two photoelectric conversion regions or photodiodes 404, are disposed under a single microlens 408. Also in this example, the light incident surface of each photodiode 404 is rectangular, and each recta shared pixel 104 has a light incident surface that is square. However, other configurations are possible. For instance, two recta shared pixels 104, each having a rectangular light incident surface can each include two square photodiodes, all disposed under a single microlens 408. As depicted in FIG. 4, all of the photodiodes 404 of recta shared pixels 104 under one microlens 408 can share a floating diffusion 412. Alternatively, separate floating diffusions can be provided for each recta shared pixel 104 or for each photodiode 404. In addition, a recta shared pixel 104 in accordance with embodiments of the present disclosure includes a control gate 416 along or adjacent to a boundary between the photodiodes 404 of the recta shared pixel 104.

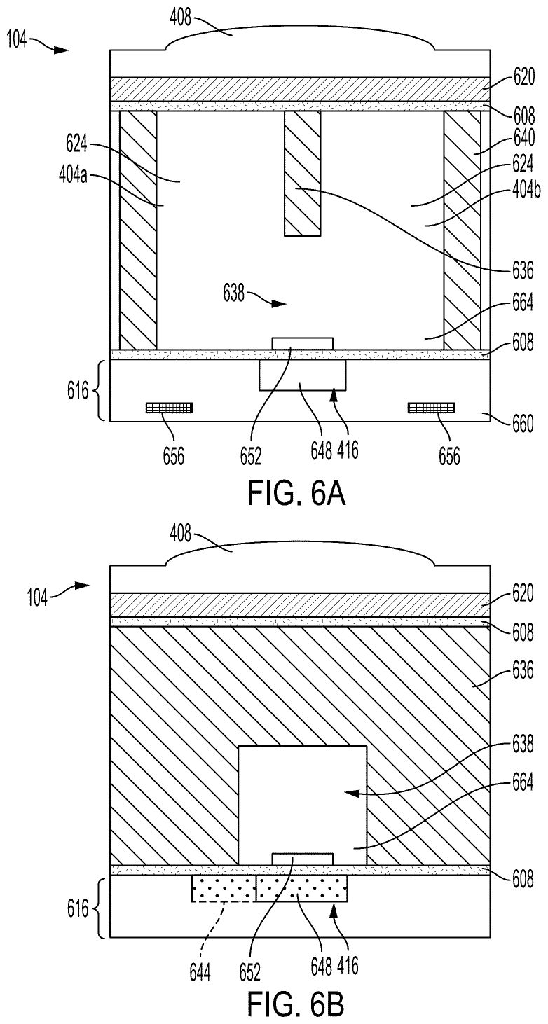

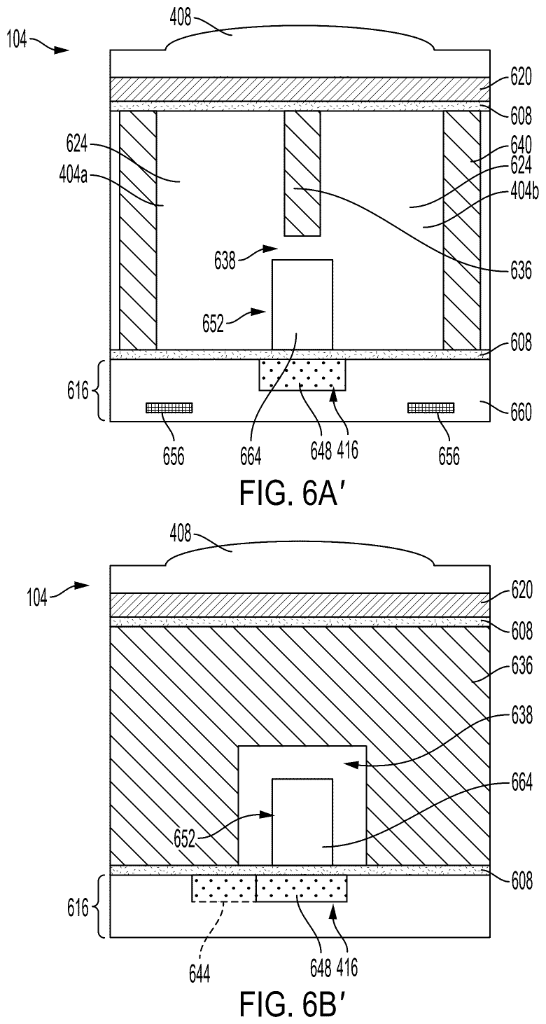

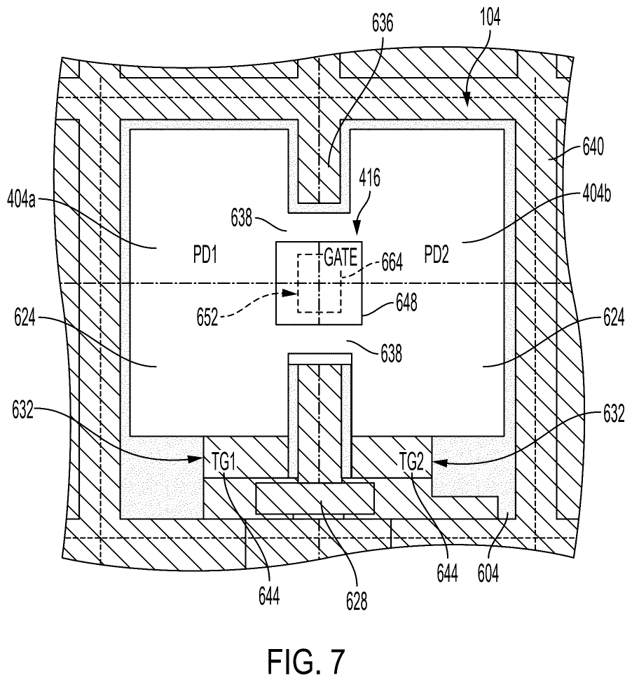

FIGS. 6A and 6A′ are cross-sections in elevation of a single recta shared pixel 104 taken along section line 6A-6A′ of the imaging device 100 of FIG. 4, FIGS. 6B and 6B′ are cross-sections in elevation of a recta shared pixel 104 taken along section line 6B-6B′ of the imaging device of FIG. 4, and FIG. 7 is a plan view of a surface opposite a light incident surface of the recta shared pixel 104 of FIGS. 6A, 6A′, 6B and 6B′. FIGS. 6A and 6B differ from FIGS. 6A′ and 6B′ in that the former depict the control gate 416 operated to form a relatively large gap or overflow path 638 between the sub-pixels 404, and the latter depict the control gate 416 operated to form a relatively small gap or overflow path 638 between the sub-pixels 404. In accordance with further embodiments of the present disclosure, a size of the overflow path 638 can be controlled to any amount between a maximum and a minimum amount. The recta shared pixel 104 is formed in a semiconductor substrate 604, and includes a wiring region 616, a color filter 620 and an on-chip lens 408.

An intra-pixel separator or intra-pixel separation structure 636 is disposed between the photodiodes 404 of the recta shared pixel 104. The intra-pixel separation structure 636 can be composed of a semiconductor region configured to have a relatively high P-type impurity concentration, and electrically separates the adjacent N-type semiconductor regions 624 of the photodiodes 404 of the recta shared pixel 104 from one another. Alternatively or in addition, the intra-pixel separation structure 636 can be formed as a trench or wall that extends between the photodiodes 404a and 404b In accordance with at least some embodiments of the present disclosure, a gap or overflow path 638 can be established between the gate electrode 648 of the control gate 416 and a nearest extent of the intra-pixel separation structure 636. The overflow path 638 can be present in one or both of cross-sectional or plan views of the recta shared pixel 104 (see FIGS. 6A and 7).

A pixel separator 640 is disposed at the boundary between adjacent recta shared pixels 104. The pixel separator 640 can be composed of a semiconductor region configured to have a relatively high P-type impurity concentration and/or a trench or wall. The pixel separator 640 electrically separates adjacent recta shared pixels 104 from one another.

The transfer gates 632 include gate electrodes 644 disposed on or adjacent to the surface opposite the light incident surface of the photodiodes 404. The control gate 416 can also include a control gate electrode 648 disposed on or adjacent to the surface opposite the light incident surface of the semiconductor substrate 604. As shown in the illustrated example, the various gate electrodes 644 and 648 can be disposed on a surface of the insulating film 608. The control gate 416 adjusts the potential barrier 652 that controls an extent of the overflow path 638. By applying voltage to the control gate 416, the height of the potential barrier 652, and thus the extent of the overflow path 638, can be adjusted. The gate electrodes 644 and 648 can be disposed in a same layer or at a same level in the recta pixel 104 structure. In accordance with further embodiments, a size, shape, or size and shape of the gate electrodes 644 and 648 can be the same. In accordance with still further embodiments, the gate electrodes 644 and 648 can be of a same material. As an example, that material can be polycrystalline silicon. The insulating films 608 between the gate electrodes 644 and 648 and a surface of the semiconductor substrate 604 can include a gate insulating film.

The wiring region 616 is disposed on a side opposite the light incident surface side of the semiconductor substrate 604 and is a region in which wirings for the recta shared pixel 104 are disposed. The wiring region 616 includes one or more wirings 656 and an insulating layer 660. A wiring 656 can transmit a signal or the like associated with a photodiode 404 of a recta shared pixel 104. A wiring 656 can be composed of a conductor, such as copper (Cu) or tungsten (W). The insulating layer 660 insulates the wiring 656, and can be composed of, for example, silicon oxide.

The insulating film 608, which is optional, provides an insulating layer over a light incident surface of the semiconductor substrate 604. For example, the insulating film 608 can be disposed between the light incident surface side of the semiconductor substrate 604 and the color filter 620. The insulating film 608 can be composed of silicon oxide or silicon nitride. The color filter 620 is an optical filter that transmits light within a predetermined range of wavelengths. The color filter 620 may be, for example, a filter that transmits red light, green light, or blue light. The on-chip lens 408 is a lens that collects incident light and directs it to the photodiodes 404. Accordingly, the on-chip lens 408 can have a generally hemispherical shape and is configured to condense light onto the photodiodes 404.

The overflow path 638 is located between the photodiodes 404 of the recta shared pixel 104. In this example, the overflow path 638 is composed of an N-type or P-type semiconductor region 664. In accordance with embodiments of the present disclosure, the control gate 416 can be operated to control a configuration of the overflow path 638. More particularly, embodiments of the present disclosure maintain the control gate 416 in an ON or relatively high voltage state by default, reducing a height of the effective potential barrier 652 between the photodiodes 404 of the recta shared pixel 104. For instance, by providing a relatively high voltage to the control gate 416, the potential barrier 652 between the photodiodes 404 can be equal or about equal to or lower than the potential barrier established by the intra-pixel separation structure 636 between the photodiodes 404 of the recta shared pixel 104. With the reduced potential barrier, the recta shared pixel 104 is advantageously configured for use in imaging operations by the imaging device 100. In addition, embodiments of the present disclosure can selectively change the control gate 416 to an OFF or relatively low voltage state, increasing a height of the effective potential barrier between the photodiodes 404 of the recta shared pixel 104. For instance, by providing a relatively low voltage to the electrode control gate 416, the potential barrier between the photodiodes 404 can be extended beyond the height of the potential barrier 652 established by the intra-pixel separation structure 636 alone.

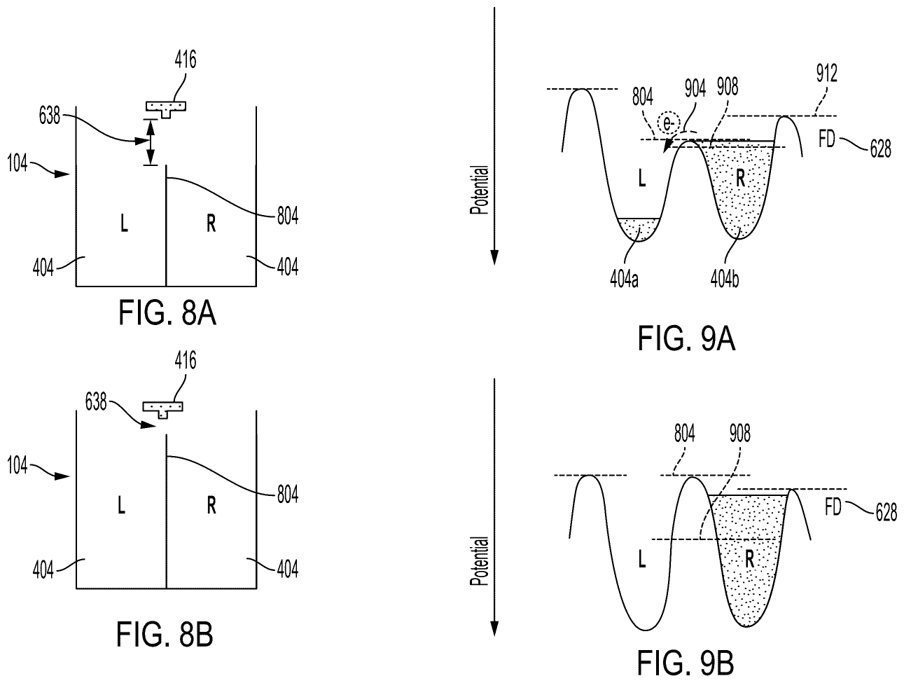

The variable nature of the effective potential barrier 804 (i.e. the barrier established by the combination of the intra-pixel separation structure 636 and the potential barrier 652) between the photodiodes 404 of a recta shared pixel 104 in accordance with embodiments of the present disclosure is depicted in FIGS. 8A-8B. In particular, in FIG. 8A the control gate 416 is in its default or high state, and the control electrode 648 is at a relatively high voltage, resulting in a relatively low effective separation or potential barrier 804 and correspondingly a relatively large overflow path 638 between the photodiodes 404. For instance, the level of the effective potential barrier 804 can be the same as or about the same as or lower than the level of separation 908 provided by the intra-pixel separation unit 636 alone (see FIG. 9A). In FIG. 8B the control gate 416 is controlled so that it is in a low state, at a relatively low voltage, resulting in a relatively high effective potential barrier 804 and correspondingly a relatively small overflow path 638 between the photodiodes 404. In particular, with the control gate 416 off, the voltage supplied to the control gate 648 is low, and a potential barrier 804 between the photodiodes 404 increases the separation between the photodiodes 404 beyond the level of separation 908 provided by the intra-pixel separation unit 636 alone (see FIG. 9B).

The effect of establishing the effective potential barrier 804 at different levels is depicted in FIGS. 9A-9B. In particular, in FIG. 9A, with the control gate 416 in a high state or ON and the control electrode 648 in the default, relatively high voltage state, the effective height of the effective potential barrier 804 between the photodiodes 404 is relatively low. In accordance with at least some embodiments, the height of the effective potential barrier 804 is the same as or about the same as or lower than the potential barrier 908 established by the intra-pixel separation structure 636 alone. As a result, when one of the photodiodes 404 is saturated, charge 904 can overflow to the other photodiode 404 along the overflow path 638, before reaching a potential 912 at which the charge would overflow to the floating diffusion 628. By avoiding overflow to the floating diffusion 628, linearity error when the recta shared pixel 104 is operating in an imaging mode is avoided. In FIG. 9A the saturation of the right side photodiode 404 and an overflow of charge 904 to the left side photodiode 404, which receives the overflow charge 904, is depicted. However, as can be appreciated by one of skill in the art after consideration of the present disclosure, the reverse situation, in which the left side photodiode 404 is saturated and on the right side photodiode 404 receives overflow charge 904 is possible.

The control gate 416 is shown in a selected relatively low voltage state, resulting in a relatively high potential barrier 804 between the photodiodes 404 of the recta shared pixel 104, in FIG. 9B. Moreover the potential barrier 804 established when the control gate 416 is in a low state or OFF and the control electrode 648 is in a relatively low voltage state, the effective height of the potential barrier 804 between the photodiodes can be significantly higher (e.g. 10-25% higher) than the height of the potential barrier 908 established by the intra-pixel separation unit 636 alone (i.e. without the influence of a voltage at the control gate 648). Accordingly, a relatively high level of separation or isolation is maintained between the photodiodes 404 when the control gate 416 is OFF. This greater level of separation is preferred when the recta shared pixel 104 is operating in phase detection autofocus mode.

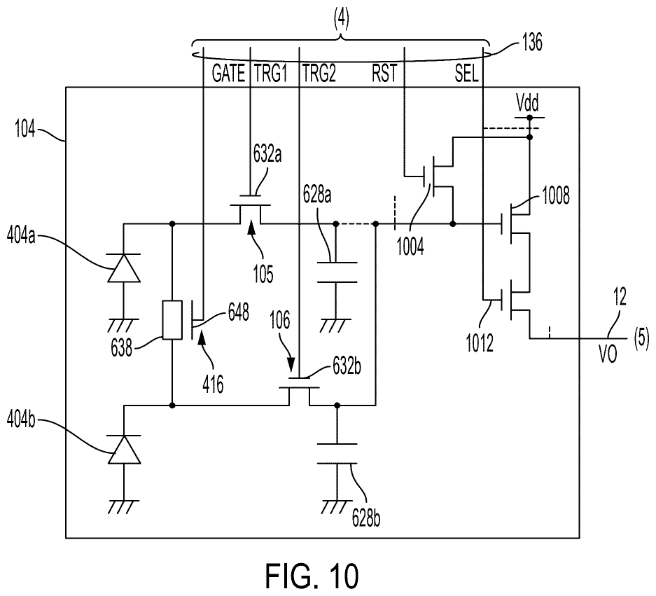

FIG. 10 is an example of a circuit configuration of a recta shared pixel 104 in accordance with embodiments of the present disclosure. In this example, the recta shared pixel 104 includes first 404a (e.g. left) and second 404b (e.g. right) photodiodes, and separate charge holding units or floating diffusions 628a and 628b, transfer gates 632a and 632b, a reset transistor 1004, an amplification transistor 1008, a selection transistor 1012, an overflow path 638, and a control gate 416. As an example, but without limitation, the transfer gates 632, the reset transistor 1004, the amplification transistor 1008, and the selection transistor 1012 can be configured by n-channel MOS transistors. Although separate floating diffusion 628 structures connected by a conductor are shown in the circuit diagram, it can be appreciated by one of skill in the art that other arrangements are possible. For instance, a single shared floating diffusion 628 structure can be provided. As another example, separate floating diffusion 628 structures that can be selectively joined to or separated from one another can be provided.

Each pixel 104 of an imaging device 100 is connected to the pixel drive wiring 136 and vertical signal lines 140. The pixel drive wiring 136 can include, for example, a control gate 416 signal line GATE, a first transfer gate 632a signal line TRG1, a second transfer gate 632b signal line TRG2, a reset transistor 1004 signal line RST, and a selection transistor 1012 signal line SEL. The pixel 104 is also connected to a power supply line Vad. Each photodiode 404 has an anode that is grounded and a cathode that is connected to an associated transfer gate 632. The drain of each transfer gate 632 is connected to the source of the reset transistor 1004 and an end of each of the floating diffusions 628. The other end of each of the floating diffusions 628 can be connected to ground. A drain of the reset transistor 1004 is connected to the power supply line Vad. The amplification transistor 1008 has a drain that is connected to the power supply line Vad and a source that is connected to the drain of the selection transistor 1012. A source of the selection transistor 1012 is connected to the signal line VO. The overflow path 638 extends between the cathodes of the photoelectric conversion sections 404.

The photodiodes 404 perform photoelectric conversion of incident light. The photodiodes 404 can be formed on or in the semiconductor substrate 604. More particularly, the photodiodes 404 perform photoelectric conversion of incident light during an exposure period. Charge generated by exposing the photodiodes 404 to incident light can be transferred to the floating diffusions 628 via the transfer gates 632. The floating diffusions 628 are semiconductor regions formed in the semiconductor substrate 604. The reset transistor 1004 resets the floating diffusions 628 by turning on and connecting the floating diffusions 628 to the power supply line Vad. The amplification transistor 1008 amplifies the voltages of the floating diffusions 628. Therefore, at the source of the amplifying transistor 1008, an image signal having a voltage corresponding to the charges held in the floating diffusions 628 is generated. By turning on the selection transistor 1012, the image signal can be output to the signal line VO.

The transfer gates 632, the reset transistor 1004, the amplification transistor 1008, and the selection transistor 1012 can be provided in the form of n-channel MOS transistors. The transistors are made conductive by applying a voltage exceeding the threshold of the gate-source voltage to the respective gate.

As discussed herein, the overflow path 638 can allow charge to overflow from one of the photodiodes 404 to the other of the photodiodes 404. The overflow path 638 can be formed within a semiconductor region disposed between the photodiodes 404. The control gate 416, which allows the potential barrier of the overflow path 638 to be adjusted, can be provided as an electrode 648 positioned adjacent to the overflow path 638.

When the recta shared pixel 104 is operated in a phase detection autofocus mode, the transfer gates 632a and 632b are operated sequentially, to individually transfer charge generated by the respective photoelectric conversion units 404a and 404b to the floating diffusions 628 at their own dedicated times. This charge transfer is referred to as individual transfer. Phase difference signals based on the charges individually transferred to the floating diffusions 628 can then be output.

When the recta shared pixel 104 is operated in an imaging mode, the transfer gates 632a and 632b are operated in unison to commonly transfer the charges generated by the photoelectric conversion units 404a and 404b to the floating diffusions 628. In the imaging mode, the floating diffusions 628 hold the charges generated by the photodiodes 404 at the same time. This charge transfer is referred to as collective transfer. An image signal based on the charges collectively transferred to the floating diffusions 628 can then be output.

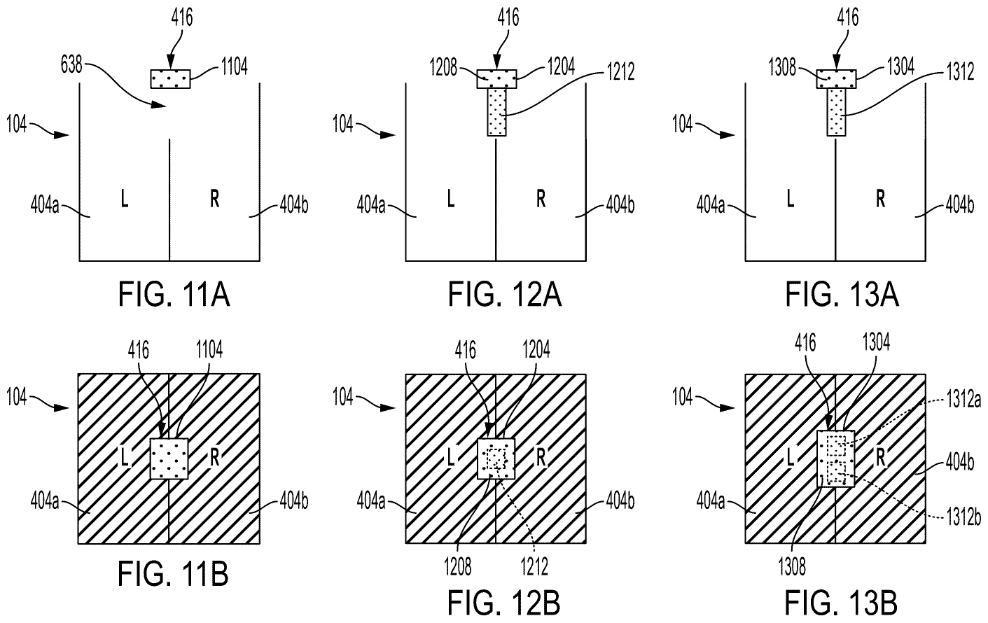

FIG. 11A is a cross-section in elevation of a recta shared pixel 104 in accordance with embodiments of the present disclosure, and FIG. 11B is a plan view of a surface of the recta shared pixel 104 of FIG. 11A. In this example, the control gate 416 has an electrode 648 that is disposed adjacent the overflow path 638 and is configured as a planar electrode 1104 disposed on a surface of the semiconductor substrate 604 in which the photodiodes 404 are formed. This configuration is suitable for an intra recta pixel overflow path located near the silicon surface opposite the microlens.

FIG. 12A is a cross-section in elevation of a recta shared pixel 104 in accordance with other embodiments of the present disclosure, and FIG. 12B is a plan view of the surface of a recta shared pixel 104 of FIG. 12A. In this example, the control gate 416 has an electrode 648 that is disposed adjacent the overflow path 638 and is configured as a single T-shaped electrode 1204, with a planar surface portion 1208 disposed on a surface of the semiconductor substrate 604, and a vertical portion 1212 that extends from the planar surface portion 1208 and towards the light incident surface side of the semiconductor substrate 604. This configuration is suitable for an intra recta pixel overflow path located away from the silicon surface opposite of microlens. The vertical portion of the T-shape electrode can be designed to reach the overflow path by adjusting the length through modification of the fabrication method.

FIG. 13A is a cross-section in elevation of a recta shared pixel 104 in accordance with other embodiments of the present disclosure, and FIG. 13B is a plan view or a surface of the recta shared 104 pixel of FIG. 13A. In this example, the control gate 416 has an electrode 648 that is disposed adjacent the overflow path 638 and is configured as a T-shaped electrode 1304 that includes a planar surface portion 1308, disposed on a surface of the semiconductor substrate 604, and a pair of vertical portions 1312a and 1312b that extend from the planar surface portion 1308 and towards the light incident surface side of the semiconductor substrate 604. This configuration maintains the benefit of depth reaching capability described in FIG. 12A while providing relatively better control over the electrical potential manipulation through the use of two electrodes.

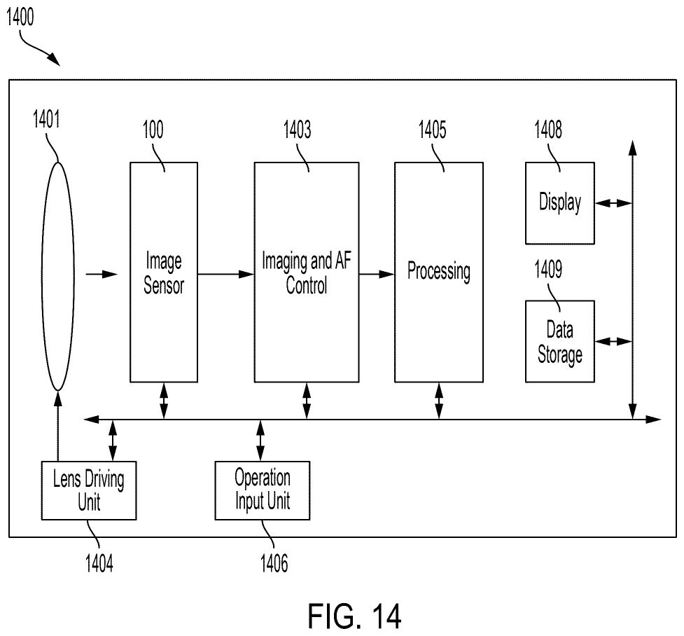

FIG. 14 is a block diagram of an imaging system incorporating an imaging device 100 in accordance with embodiments of the present disclosure. In this example, the imaging system is in the form of a camera 1400. As depicted in the figure, the camera 1400 includes an optical system or lens 1401, an imaging device 100 having a plurality of recta shared pixels 104 as disclosed herein, an imaging and autofocus control unit 1403, a lens driving unit 1404, an image processing unit 1405, an operation input unit 1406, a display unit 1408, and a recording unit 1409.

The optical system 1401 includes an objective lens of the camera 1400. The optical system 1401 collects light from within a field of view of the camera 1400, which can encompass a scene containing an object. As can be appreciated by one of skill in the art after consideration of the present disclosure, the field of view is determined by various parameters, including a focal length of the lens, the size of the effective area of the array 108 of pixels 104 of the imaging device 100, and the distance of the array 108 from the lens. In addition to a lens, the optical system 1401 can include other components, such as a variable aperture and a mechanical shutter. The optical system 1401 directs the collected light to the imaging device 100 to form an image of the object on a light incident surface of the imaging device 100.

As discussed elsewhere herein, the imaging device 100 includes a plurality of recta shared pixels 104 disposed in an array 108. Moreover, the imaging device 100 can include a semiconductor element or substrate 112 in which the recta shared pixels 104 each include a number of photodiodes 404 that are formed as photosensitive areas within the substrate 112. In addition, as also described elsewhere herein, each recta shared pixel 104 can be selective operated in either an imaging mode, which is the default mode, or a phase detection auto focus mode. The photodiodes 404 generate an amount of charge that is proportional to an amount of light incident thereon. These signals can be converted into digital signals in a circuit, such as a column signal processing circuit 120, included as part of the imaging sensor 100, or in a separate circuit or processor. The signals can then be output.

The imaging control unit 1403 controls imaging operations of the image imaging device 100 by generating and outputting control signals to the imaging device 100. Further, the imaging control unit 1403 can perform autofocus in the camera 1400 on the basis of image signals output from the imaging device 100. Here, “autofocus” is a system that detects the focus position of the optical system 504 and automatically adjusts the focus position. For example, a method in which an image plane phase difference is detected by operating some or all of the recta shared pixels 104 of the imaging device 100 in a phase difference detection mode (image plane phase difference autofocus) can be used. The imaging control unit 1403 adjusts the position of the lens 1001 through the lens driving unit 1404 on the basis of the detected focus position, to thereby perform autofocus. Note that the imaging control unit 1403 can include, for example, a DSP (Digital Signal Processor) equipped with firmware.

The lens driving unit 1404 drives the optical system 504 on the basis of control of the imaging control unit 1403. The lens driving unit 1404 can drive the optical system 1401 by changing the position of included lens elements using a built-in motor.

The image processing unit 1405 processes image signals generated by the imaging device 100. The image processing unit 1405 can include, for example, a microcomputer equipped with firmware, and/or a processor that executes application programming, to implement processes for identifying color information in collected image information as described herein.

The operation input unit 1406 receives operation inputs from a user of the camera 1400. As the operation input unit 1406, for example, a push button or a touch panel can be used. An operation input received by the operation input unit 1406 is transmitted to the imaging control unit 1403 and the image processing unit 1405. After that, processing corresponding to the operation input, for example, the collection and processing of imaging an object or the like, is started.

The display unit 1408 can display information processed by the image processing unit 1405. For example, a liquid crystal panel can be used as the display unit 1408.

The recording unit 1409 records image data processed by the image processing unit 1405. As the recording unit 1409, for example, a memory card or a hard disk can be used.

An example of a camera 1400 to which embodiments of the present disclosure can be applied has been described above. The imaging device 100 of the camera 1400 can be configured as described herein. Specifically, the imaging device 100 can include a plurality of recta shared pixels 104. Each of the recta shared pixels 104 can by default be operated with a relatively low potential barrier between included photodiodes 404 in an imaging mode, and can be selectively operated with a relatively high potential barrier between the included photodiodes 404 in a phase difference detection autofocus mode.

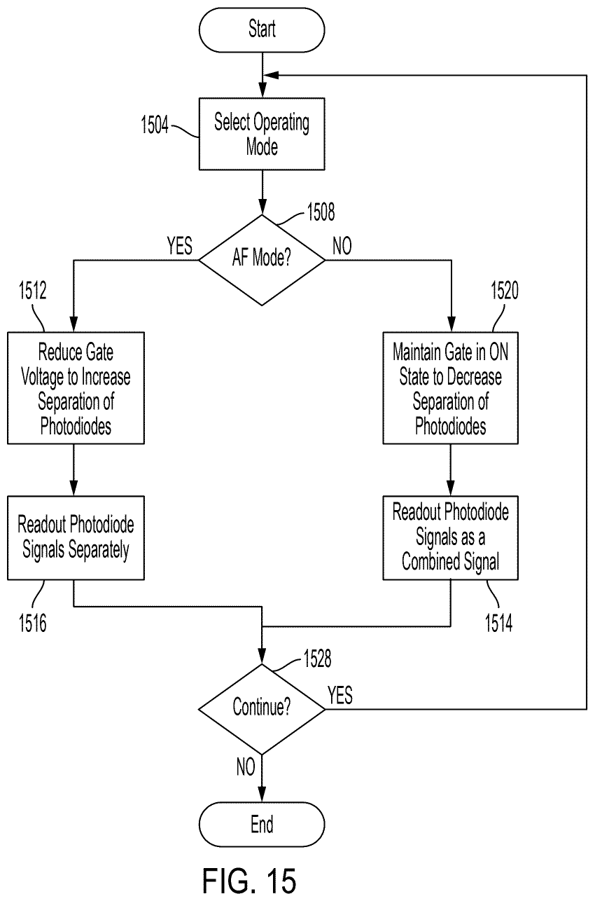

FIG. 15 is a flowchart depicting aspects of a method for operating an imaging device or sensor 100 incorporating a plurality of recta shared pixels in accordance with embodiments of the present disclosure. Initially, at step 1504, an operating mode for the imaging sensor 100 is selected. In accordance with embodiments of the present disclosure, a default operating mode for the imaging sensor 100 is an imaging mode, in which a relatively low potential barrier is maintained between the photodiodes 404 of some or all of the recta shared pixels 104. The operating mode for the imaging sensor 100 may be determined by, for example, operation of a processor 1405 of a camera 1400 or other system incorporating the imaging sensor 100.

At step 1508, the selected operating mode is detected. In response to determining that the phase detection autofocus mode has been selected, the control gate 648 is placed in a relatively low voltage state, which has the effect of raising the potential barrier between the photodiodes 404 of the recta shared pixels 104 (step 1512). An amount of charge generated in the photodiodes 404 of the recta shared pixels 104 is then read out separately for each of the recta shared pixels 104 included in the auto focus operation (step 1516). As can be appreciated by one of skill in the art after consideration of the present disclosure, the relative amount of charge produced by the different photodiodes 404 within a given recta shared pixel 104 can indicate a focus state of the optical system 1401. In particular, where the amount of charge generated by the photodiodes 404 within a given recta shared pixel 104 are equal, an “in-focus” state is indicated by that recta shared pixel 104. Where the amount of charge generated by the photodiodes 404 of a given recta shared pixel 104 are different, an “out-of-focus” state is indicated by that recta shared pixel 104. In accordance with further embodiments of the present disclosure, the identity of the photodiode 404 within a recta shared pixel 104 that has a greater amount of relative charge as compared to the other photodiode 404 can indicate a direction in which the lens driving unit 1404 should drive the optical system 1401 in order to achieve and an in focus state.

In response to determining at step 1508 that in imaging mode has been selected, the control gate 648 is maintained in its default condition, in which the control gate 648 is held at a relatively high voltage or “ON” state, which has the effect of lowering the potential barrier between the photodiodes 404 of the recta shared pixels 104 (step 1520). An amount of charge generated in the photodiodes 404 of the recta shared pixels 104 is then read out collectively for each of the recta shared pixels 104 included in the imaging operation (step 1524).

After reading out the photodiode signals 404 from recta shared pixels 104 individually at step 1516, or after reading out the photodiode signals 404 from recta shared pixels 104 collectively at step 1524, a determination can be made as to whether operation of the imaging sensor 100 should continue (step 1528). If operation is to continue, the process can return to step 1504. Otherwise the process can end. As can be appreciated by one of skill in the art after consideration of the present disclosure, operation of recta shared pixels 104 in a phase detection autofocus mode can include operating those recta shared pixels 104 within selected areas or autofocus zones of an array 108 of recta shared pixels 104. As can also be appreciated by one of skill in the art after consideration of the present disclosure, in an imaging mode signals from all of the recta shared pixels 104 within the imaging sensor 100 are typically used to generate an image.

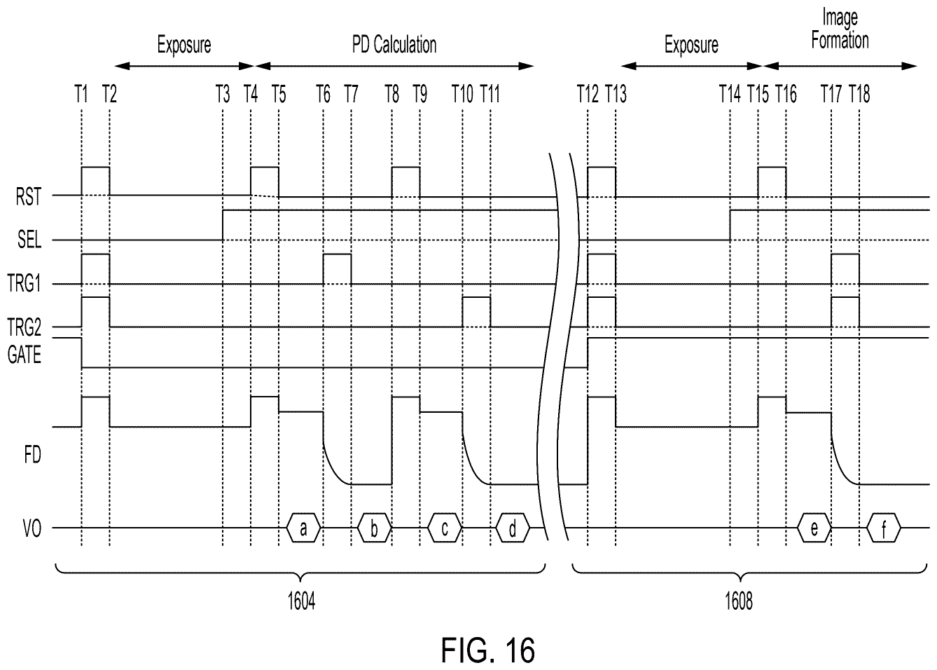

FIG. 16 is a timing diagram depicting the operation of a recta shared pixel 104 of an imaging sensor 100 in accordance with embodiments of the present disclosure. More particularly, an example of the generation of an image signal and the generation of a phase difference autofocus signal according to embodiments of the present disclosure are illustrated. “RST”, “SEL”, “TRG1”, “TRG2”, and “GATE” in the figure represent signals on the signal line RST, the signal line SEL, the signal line TRG1, the signal line TRG2, and the signal line GATE respectively. More particularly, the signals are represented as waveforms of the binarized control signals. “FD” in the figure represents the potential of the floating diffusions 628. “VO” represents the output of the signal line VO. The procedure for operating the imaging sensor 100 in a phase detection autofocus mode is shown in the first half of the FIG. 1604, and the procedure for operating the imaging sensor 100 in an imaging mode is shown in the second half of the FIG. 1608.

In the initial state, a value “0” (i.e. a low value) is applied to the signal line RST, the signal line SEL, the signal line TRG1, and the signal line TRG2. A value “1” (i.e. a high value) is applied to the signal line GATE, which is connected to the control gate 416, in the initial state. Moreover, the control gate 416 is held at a high value, and thus in an “ON” state, by default. That is, apart from the time during which the associated recta shared pixel 104 is being operated in a phase detection autofocus mode, the control gate 416 is provided with a relatively high voltage, which corresponds to a low potential barrier between the photodiodes 404 of the recta shared pixel 104.

At T1, an “ON” signal is applied to the signal lines RST, TRG1, and TRG2. As a result, the reset transistor 1004 and the transfer gate 632a become conductive, and the photodiodes 404 and the floating diffusions 628 are reset. In addition, at time T1 the signal line GATE, which had been applying a relatively high voltage to the control gate 416, is brought to a relatively low voltage.

At T2, application of “ON” signals to the signal lines RST, and TRG1 is stopped. For example, a voltage or signal on each of the signal lines RST and TRG1 is changed from a high to a low value. As a result, an exposure period is started, and charges generated by photoelectric conversion of incident light are accumulated in the photodiodes 404 of the recta shared pixel 104. At T2, GATE still maintains an “OFF” signal position. As the potential barrier between the photodiodes 404 is in a raised state when a relatively low voltage is applied to the control gate 416 by the GATE signal line, the overflow path 638 between the photodiodes 404 is relatively constricted. Accordingly, when the exposure period for a phase detection autofocus procedure starts, the potential barrier is configured for enhanced separation between the photodiodes 404, and thus a favorable separation ratio between the photodiodes 404 is established.

At T3, an “ON” signal is applied to the signal line SEL. The application of the ON signal to the signal line SEL continues until the phase difference signals of all of the pixels 104 and the selected pixel region are output.

At T4, an “ON” signal is applied to the signal line RST, and the floating diffusions 628 are reset.

At T5, application of the “ON” signal to the signal line RST is stopped. The signal “a” at the time of resetting is output from the signal line VO from time T5 until time T6.

At T6, an “ON” signal is applied to the signal line TRG1. This causes the first transfer gate 632a to become conductive, allowing the charges accumulated in the first photodiode 404a to be transferred to the floating diffusions 628, and the exposure period for photodiode 404a ends.

At T7, application of the “ON” signal to the signal line TRG1 is stopped. From time T7 to time T8 the image signal “b” corresponding to the charge of the photodiode 404a is output from the signal line VO. Correlated double sampling is then performed using the image signal “a” and image signal “b” to generate a first phase difference signal for the recta shared pixel 104.

At T8, an “ON” signal is applied to the signal line RST, and the floating diffusions 628 are reset.

At T9, application of the “ON” signal to the signal line RST is stopped. from time T9 until time T10 the reset image signal “c” is output from the signal line VO.

At T10, an “ON” signal is applied to the signal line TRG2. This causes the second transfer gate 632b to become conductive, allowing the charges accumulated in the second photodiode 404b to be transferred to the floating diffusion 628, and the exposure period for photodiode 404b ends.

At T11, application of the “ON” signal to the signal line TRG2 is stopped. An image signal “d” corresponding to the charge of the photodiode 404a is output from the signal line VO. Correlated double sampling is then performed using the image signal “c” and the image signal “d” to generate a second phase difference signal for the recta shared pixel 104. The first and second phase difference signals can then be compared to determine a focus state of light incident on the recta shared pixel 104.

Next, an imaging operation 1608 is explained. At T12, an “ON” signal is applied to the signal lines RST, TRG1, TRG2, and GATE. As a result, the reset transistor 1004 and the transfer gates 632 become conductive, and the photodiodes 404 and the floating diffusions 628 are reset. In addition, as a relatively high voltage is applied to the control gate 648 by the signal line GATE, the potential barrier between the photodiodes is held at a low level.

At T13, application of the “ON” signal to the signal lines RST, TRG1, and TRG2 is stopped. As a result, an exposure period of the imaging operation 1608 is started, and charges generated by photoelectric conversion are accumulated in the photodiodes 404.

At T14, an “ON” signal is applied to the signal line SEL. The application of the “ON” signal to the signal line SEL continues until the image signals of all of the recta shared pixels 104 in the pixel region are output.

At T15, an “ON” signal is applied to the signal line RST, and the floating diffusions 628 are reset. The exposure period ends at T15.

At T16, application of the “ON” signal to the signal line RST is stopped. the image signal “e” at the time of resetting is output from the signal line VO until T17.

At T17, an “ON” signal is applied to the signal lines TRG1 and TRG2. The transfer gates 632 therefore become conductive, and charges accumulated in the photodiodes 404 are transferred to the floating diffusions 628.

At T18, application of the “ON” signal to the signal lines TRG1 and TRG2 is stopped. After that, an image signal “f” corresponding to the charges of both of the photodiodes 404 within the recta shared pixel 104 is output from the signal line VO. Correlated double sampling is then performed using the image signals “e” and “f” to generate an image signal.

Notably, the voltage supplied to the control gate 648 by the GATE signal line remains high throughout the imaging operation 1608. Accordingly, a potential barrier between the photodiodes 404 of the recta shared pixel 104 is relatively low, reducing the likelihood that charge will overflow to a floating diffusion 628 during an imaging operation 1608. In addition, maintaining a high voltage at the control gate 648 can be additionally advantageous in that a high positive voltage, as maintained during all but during a phase detection autofocus operation, allows the photodiodes 404 to hold more charge than if the control gate 648 were at a lower voltage or a negative voltage. This in turn can result in increased dynamic range as compared to an otherwise similar photodetector in which a high positive voltage is not maintained during most phases of operation.

The foregoing has been presented for purposes of illustration and description. Further, the description is not intended to limit the disclosed systems and methods to the forms disclosed herein. Consequently, variations and modifications commensurate with the above teachings, within the skill or knowledge of the relevant art, are within the scope of the present disclosure. The embodiments described hereinabove are further intended to explain the best mode presently known of practicing the disclosed systems and methods, and to enable others skilled in the art to utilize the disclosed systems and methods in such or in other embodiments and with various modifications required by the particular application or use. It is intended that the appended claims be construed to include alternative embodiments to the extent permitted by the prior art.

What is claimed is:

1. An imaging device, comprising:
a semiconductor substrate; and
a plurality of recta shared pixels disposed in the semiconductor substrate, wherein each recta shared pixel includes:
a first photoelectric conversion region;
a second photoelectric conversion region;
an intra-pixel separation structure, wherein the intra-pixel separation structure establishes a separation barrier between the first photoelectric conversion region from the second photoelectric conversion region;
a control gate; and
a path between the separation structure and the control gate, wherein in a default mode of operation a first voltage is supplied to the control gate to increase an effective size of the path, lowering a potential barrier between the first photoelectric conversion region and the second photoelectric conversion region, wherein in another mode of operation a second voltage is supplied to the control gate to reduce the effective size of the path, raising the potential barrier between the first photoelectric conversion region and the second photoelectric conversion region, and wherein the first voltage is higher than the second voltage.

2. The imaging device of claim 1, wherein the control gate includes a control gate electrode, and wherein the first voltage is supplied to the control gate electrode in the default mode of operation, and wherein the second voltage is supplied to the control gate electrode in the other mode of operation.

3. The imaging device of claim 2, wherein a gap is present between the intra-pixel separation structure and the control gate electrode.

4. The imaging device of claim 3, wherein the control gate electrode includes a planar structure adjacent to a surface of the semiconductor substrate opposite a light incident surface of the semiconductor substrate.

5. The imaging device of claim 4, wherein the control gate electrode further includes a vertical portion that extends towards the light incident surface of the semiconductor substrate.

6. The imaging device of claim 4, wherein the control gate electrode further includes first and second vertical portions that extend toward the light incident surface of the semiconductor substrate.

7. The imaging device of claim 2, wherein each recta shared pixel further includes:
a first transfer gate, wherein the first transfer gate selectively connects the first photoelectric conversion region to a first floating diffusion; and
a second transfer gate, wherein the second transfer gate selectively connects the second photoelectric conversion region to a second floating diffusion.

8. The imaging device of claim 7, wherein the first transfer gate includes a first transfer gate electrode, wherein the second transfer gate includes a second transfer gate electrode, and wherein the first and second transfer gate electrodes are on a same plane as the control gate electrode.

9. The imaging device of claim 8, wherein the first transfer gate is a same size as the second transfer gate.

10. The imaging device of claim 9, wherein the first transfer gate is a same shape as the second transfer gate.

11. The imaging device of claim 10, wherein the control gate is a same material as the first and second transfer gates.

12. The imaging device of claim 11, wherein the control gate is a same shape as the first and second transfer gates.

13. The imaging device of claim 1, wherein the first photoelectric conversion region is a first photodiode, and wherein the second photoelectric conversion region is a second photodiode.

14. A system, comprising:
an imaging lens;
an image sensor, the image sensor including:
a plurality of recta shared pixels disposed in an array, wherein each recta shared pixel in the plurality of recta shared pixels includes:
a first photoelectric conversion region;
a second photoelectric conversion region;
an intra-pixel separation structure, wherein the intra-pixel separation structure establishes a separation barrier between the first photoelectric conversion region from the second photoelectric conversion region; and
a control gate, wherein the control gate is disposed adjacent to the intra-pixel separation structure, wherein in a default mode of operation a first voltage is supplied to the control gate to lower an effective potential barrier between the first photoelectric conversion region and the second photoelectric conversion region, wherein in another mode of operation a second voltage is supplied to the control gate to raise the effective potential barrier between the first photoelectric conversion region and the second photoelectric conversion region, and wherein the first voltage is higher than the second voltage; and
a processor, wherein in a default mode the control gate of at least some of the recta shared pixels are supplied with a first voltage and an effective potential barrier between the first and second photoelectric conversion regions of the at least some of the recta shared pixels is equal to or less than a potential barrier established by the intra-pixel separation structure alone, wherein in another mode of operation the control gate of the at least some of the recta shared pixels is supplied with a second voltage and the effective potential barrier between the photoelectric conversion regions is greater than the effective potential barrier between the photoelectric conversion regions when first voltage is supplied to the control gate of the at least some of the recta shared pixels, and wherein the first voltage is higher than the second voltage.

15. A method, comprising:
providing an image sensor having a semiconductor substrate and a plurality of recta shared pixels disposed in the semiconductor substrate, wherein each recta shared pixel includes:
a first photoelectric conversion region;
a second photoelectric conversion region;
an intra-pixel separation structure, wherein the intra-pixel separation structure establishes a separation barrier between the first photoelectric conversion region from the second photoelectric conversion region; and
a control gate, wherein the control gate is disposed adjacent to the intra-pixel separation structure;
supplying a first voltage to the control gates of the recta shared pixels to lower an effective potential barrier between the first photoelectric conversion region and the second photoelectric conversion region of each of the recta shared pixels in a default mode of operation;
supplying a second voltage to the control gates of the recta shared pixels to raise the effective potential barrier between the first photoelectric conversion region and the second photoelectric conversion region of each of the recta shared pixels in another mode of operation,
wherein the first voltage is higher than the second voltage,
wherein the default mode of operation includes an imaging mode, and
wherein the other mode of operation includes a phase detection autofocus mode.

16. The method of claim 15, wherein the second voltage is only supplied to the control gates of the recta shared pixels during the phase detection autofocus mode.

17. The method of claim 15, wherein the effective potential barrier in the phase detection autofocus mode of operation is greater than a potential barrier established by the intra-pixel separation structure alone.

18. The method of claim 15, wherein the effective potential barrier in the imaging mode of operation is equal to or less than a potential barrier established by the intra-pixel separation structure alone.

19. The method of claim 15, wherein the intra-pixel separation structure is separated from the control gate by a gap.

20. The method of claim 15, wherein the photoelectric conversion regions are photodiodes.
